(19) United States
(12) Patent Application Publication
(10) Pub. No.: US 2025/0241203 A1
(43) Pub. Date: Jul. 24, 2025

(54) SEMICONDUCTOR MATERIAL AND MULTILAYER SEMICONDUCTOR MATERIAL

(71) Applicant: TOHOKU UNIVERSITY, Sendai-Shi, Miyagi (JP)

(72) Inventors: Mikio FUKUHARA, Sendai-shi (JP); Toshiyuki HASHIDA, Sendai-shi (JP); Tomonori YOKOTSUKA, Sendai-shi (JP)

(73) Assignee: TOHOKU UNIVERSITY, Sendai-Shi, Miyagi (JP)

(21) Appl. No.: 18/855,544

(22) PCT Filed: Feb. 13, 2023
(86) PCT No.: PCT/JP2023/004701

§ 371 Date: Oct. 9, 2024

(30) Foreign Application Priority Data
Apr. 20, 2022 (JP) 2022-069574

(51) Int. Cl. H10K 85/00; D21H 11/04; D21H 11/12; D21H 11/18; D21H 13/30; D21H 27/30

(52) U.S. Cl. CPC H10K 85/761; D21H 11/04; D21H 11/12; D21H 11/18; D21H 13/30; D21H 27/30

(57) ABSTRACT

A semiconductor material and a multilayer semiconductor material are earth-conscious and are less harmful to living organisms. The semiconductor material has fibers containing, as a main component, a filament derived from at least any one of a wood material, a plant fiber (pulp), an animal, an alga, a microorganism and a product produced by a microorganism, and has N-type negative resistance. It is preferred that the fibers include bundles of cellulose nanofibers (CNFs), and the width of each of the bundles be 30 to 50 nm. It is also preferred that the fibers are fibers in which a plurality of hydroxy groups and a plurality of carbonyl groups be bound to cellulose.

### FIELD OF THE INVENTION

The present invention relates to a semiconductor material and a multilayer semiconductor material.

### DESCRIPTION OF RELATED ART

Semiconductors utilize properties in which electrical conductivity is significantly changed due to impurity introduction and influences from e.g. heat, light, a magnetic field, voltage, current and radiation, and are used for high voltage power circuits (strong electricity) and electronic and electrical equipment circuits (weak electricity). Semiconductors are widely utilized particularly for weak electric elements such as a variety of diodes, transistors, FETs, SITs, RAMs, ROMs and CCDs, and are an essential electronic component for electronic equipment. In recent years, high-tech IT products such as mobile phones and ultra-compact storages and electric vehicle batteries have rapidly advanced, and much smaller high-tech semiconductors with a greater capacity have been increasingly demanded. Among these, particularly, semiconductors which conform to the smart grid (next generation power grid) society consistent with green innovation (low carbonization) for prevention of global warming have been required.

Inorganic materials and organic materials have been used as semiconductor materials in the past. Si and compound semiconductors are mainly used as semiconductor materials for electronic and electric equipment circuits in the weak electric field, and metal/semiconductor-type transistors including an amorphous Ni—Nb—Zr—H alloy as a material, for example, have been developed by the present inventors (see e.g. Non-Patent Literatures 1 to 5 and Patent Literature 1). In addition, organic semiconductors are also used as a component of organic ELs, which have been a main member for televisions and smartphone products, and organic solar cells (see e.g. Patent Literature 2).

### CITATION LIST

### Non-Patent Literatures

Non-Patent Literature 1: M. Fukuhara, A. Kawashima, S. Yamaura, and A. Inoue, “Coulomb oscillation of a proton in a Ni—Nb—Zr—H glassy alloy with multiple junctions”, Appl. Phys., 2007, 90, 203111
Non-Patent Literature 2: M. Fukuhara and A. Inoue, “Room-temperature Coulomb oscillation of a proton dot in Ni—Nb—Zr—H glassy alloys with nanofarad capacitance”, J. Appl. Phys., 2009, 105, 063715
Non-Patent Literature 3: M. Fukuhara, H. Yoshida, K. Koyama, A. Inoue, and Y. Miura, “Electronic transport behaviors of Ni—Ngb-Zr—H glassy alloys”, J. Appl. Phys., 2010, 107, 033703
Non-Patent Literature 4: M. Fukuhara, H. Yoshida, and H. Kawarada, “Effect of hydrogen and cluster morphology on the electronic behavior of Ni—Nb—Zr—H glassy alloys with subnanometer-sized icosahedral Zr5Ni5Nb5 clusters”, Euro. Phys. J., 2013, D 67, 40
Non-Patent Literature 5: M. Fukuhara and H. Kawarada, “Room-temperature amorphous alloy field-effect transistor exhibiting particle and wave electronic transport”, J. Appl. Phys., 2015, 117, 084302

### PATENT LITERATURES

Patent Literature 1: WO2011/037003
Patent literature 2: JP-A-2019-130524

### SUMMARY OF THE INVENTION

Conventional semiconductor materials including an inorganic material as described in Non-Patent Literatures 1 to 5 and Patent Literature 1 are those which are artificially synthesized, and there have been problems in that many of them are harmful to global environmental protection and the existence of living organisms including human lives. A semiconductor material used, therefore, is desirably one that does not contain toxic elements such as arsenic, lead, cadmium, beryllium and mercury and environmental pollutants such as lithium, chromium and sulfur, and is harmless to health. In conventional organic semiconductor materials as described in Patent Literature 2, there are those which cause an increase in carbon dioxide and those which become microplastics causing marine pollution when discarded, and there have been problems in that many of them are harmful to global environmental protection and living organisms.

The present invention has been made by focusing on such problems, and an object thereof is to provide a semiconductor material and a multilayer semiconductor material, which are earth-conscious and are less harmful to living organisms.

The present inventors found that using as a solid semiconductor material a material with semiconductor conductivity such as a cellulose fiber or pulp, an aggregate thereof, the performance of a diode and transistor was expressed, and focused on fibers containing e.g. a wood material or a plant fiber (pulp) as a main component, thereby leading to the present invention.

That is, in order to achieve the above object, the semiconductor material according to the present invention is characterized by having fibers containing, as a main component, a filament derived from at least any one of a wood material, a plant fiber (pulp), an animal, an alga, a microorganism and a product produced by a microorganism, and having N-type negative resistance.

The fibers containing, as a main component, a filament derived from at least any one of a wood material, a plant fiber (pulp), an animal, an alga, a microorganism and a product produced by a microorganism are not environmental pollutants but recyclable, have smaller environmental load in the production and disposal, and are harmless or less harmful to earth environments and living organisms. The semiconductor material according to the present invention has such fibers containing, as a main component, a filament derived from at least any one of a wood material, a plant fiber (pulp), an animal, an alga, a microorganism and a product produced by a microorganism, is earth-conscious and is less harmful to living organisms.

Herein the “fibers containing, as a main component, a filament derived from at least any one of a wood material, a plant fiber (pulp), an animal, an alga, a microorganism and a product produced by a microorganism” are fibers containing the maximum mass percentage of a filament containing, as a source component, cellulose contained in at least any one of a wood material, a plant fiber (pulp), an animal, an alga, a microorganism and a product produced by a microorganism.

The semiconductor material according to the present invention is preferably an n-type semiconductor. At this time, the semiconductor material according to the present invention is an n-type semiconductor having N-type negative resistance, and can be utilized as a DC/AC converter element, a 10⁴-order semiconductor/metallic conductivity switching element, and a rectifier circuit element.

In the semiconductor material according to the present invention, the fibers are preferably those which include a thin film and in which an electric double layer of electrons and protons can be formed in the thin film, and are particularly preferably fibers in which a plurality of hydroxy groups and a plurality of carbonyl groups are bound to cellulose. In this case, a high dielectric domain structure is formed by the formed electric double layer, and also proton tunneling (solitonized proton) is formed by the quantum size effect, and therefore semiconductor characteristics can be expressed. In addition, condensers each having numerous overlapped electric double layers in one thin film are joined in series finitely to form a macroscopic electric lumped constant circuit, and therefore a transistor which expresses various functions by dielectric response and direct current, for example, can be formed. It should be noted that in cellulose, a polysaccharide, represented by the molecular formula (C₆H₁₀O₅)ₙ, β-glucoses are polymerized and thus the molecules are bound by hydrogen bonds to easily form a sheet shape. When hydroxyl groups (OH groups) and carbonyl groups (C—O groups) are bound to the cellulose, dipoles ordered in the same direction are considered to be formed and structurally act in the same manner as the one-dimensional hydrogen bond chain of water. That is, it is considered that by behavior like chained protonic solitons, an electric double layer, a base of proton transfer, can be instantly formed.

In the semiconductor material according to the present invention, the fibers may include, for example, pulp, a cellulose fiber or a cellulose nanofiber (CNF). In particular, in order to further increase the forming efficiency of the electric double layer, the fibers preferably include bundles of CNFs, and the width of the bundles is 30 to 50 nm. In addition, the aspect ratio of the bundles of CNFs is preferably 1 to 200 and particularly preferably 1 to 10. When the aspect ratio of the bundles of CNFs is above 200, the fibers are entangled with each other to form holes, and thus the efficiency is reduced. When the aspect ratio is smaller than 1, strength is reduced. CNF can increase the electron adsorption ability due to the quantum size effect with a minus sixth power law, and thus when the fibers include CNFs, the work function can be increased to further expand the dielectric domain, and the performance as a semiconductor can be increased.

In the semiconductor material according to the present invention, when the fibers include pulp or a cellulose fiber, the type of cellulose is not particularly limited, and cellulose originated from a plant (for example, a wood material, bamboo, hemp, jute, kenaf, farm waste, fabric, pulp (nadelholz unbleached kraft pulp (NUKP), nadelholz bleached kraft pulp (NBKP), laubholz unbleached kraft pulp (LUKP), laubholz bleached kraft pulp (LBKP), nadelholz unbleached sulfite pulp (NUSP), nadelholz bleached sulfite pulp (NBSP), thermomechanical pulp (TMP), recycled pulp, used paper or the like), an animal (for example, sea squirts), an alga, a microorganism (for example, Acetobacteraceae (Acetobacter)), or a product produced by a microorganism, for example, can be used. Cellulose derived from a plant or a microorganism is preferred, and cellulose derived from a plant is more preferred. In addition, when the fibers include CNFs, the width of each of the CNFs is preferably about 3 to 4 nm, and CNFs may not be modified or may be chemically modified. It should be noted that the width of CNFs is a mean filament diameter, which is obtained by averaging filament diameters from the observation results of filaments using an atomic force microscope (AFM) or a transmission electron microscope (TEM).

In the semiconductor material according to the present invention, the fibers are preferably amorphous, but nanocrystals may exist therein. In addition, the fibers may have an atomic vacancy. In addition, the fibers are preferably formed using e.g. a wood material or a plant fiber (pulp) as a raw material by a mechanical defibration method or a chemical defibration method such as a phosphate esterification method.

The semiconductor material according to the present invention includes a bulk semiconductor represented by an equivalent circuit in which a first RC parallel circuit and a second RC parallel circuit are connected in parallel, and the second RC parallel circuit has preferably resistance with a greater resistance value than that of the resistance of the first RC parallel circuit and a condenser with a greater capacity than that of the condenser of the first RC parallel circuit. In this case, the first RC parallel circuit and the second RC parallel circuit indicate an electric double layer in the fibers, and can express semiconductor characteristics.

In addition, in this case, the fibers have a thin film sheet shape, and may have a pair of metal electrodes provided on both surfaces of the fibers so that the fibers will be placed between the electrodes. In this case, this material is equivalent to a lumped constant condenser having two macroscopic condensers between the metal electrodes. That is, a semiconductor having two bands, a low current low resistance band and a high current high resistance band, can be formed. Each metal electrode includes, for example, Al, Cu, gold, graphite, polyacetylene or polythiophene, and is preferably formed using a Micro (Nano) Electro Mechanical System (M (N) EMS) by a sputtering method, a cast method or an electrodeposition method.

Since weight reduction is expected, the semiconductor material according to the present invention preferably has a thin film shape with a thickness of 100 μm or less and desirably 5 μm or less. In addition, the semiconductor material according to the present invention has an electric resistivity of 10⁻³ Ωcm or more and 10⁸ Ωcm or less and preferably 10¹ Ωcm or more and 10⁶ Ωcm or less, and an electrical capacity of preferably 0.1 mF/cm² or more and more preferably 5 mF/cm² or more. It is also preferred that the semiconductor material according to the present invention have a specific surface area of 800 m²/g or more. It is also preferred that the semiconductor according to the present invention be able to operate at −269° C. to 200° C.

The multilayer semiconductor material according to the present invention is characterized by including a laminated body in which a plurality of the semiconductor materials according to the present invention are laminated. In this case, the semiconductor materials according to the present invention can be laminated in series, for example, by various M (N) EMS methods, and a solid quantum semiconductor in which series equivalent circuits are bonded to each other in an electric lumped constant manner can be obtained. In addition, the semiconductor material according to the present invention has a pair of metal electrodes, includes a plurality of fibers, and may include a parallel integrated body in which fibers are arranged along the inner side surface of each metal electrode between the metal electrodes. In this case, a voltage resistance of 1 MV/m or more can be also obtained.

According to the present invention, it is possible to provide a semiconductor material and a multilayer semiconductor material, which are earth-conscious and are less harmful to living organisms.

### BRIEF DESCRIPTION OF THE DRAWINGS

FIG. 1 is an electric circuit diagram showing an equivalent circuit of a semiconductor material in the embodiment of the present invention.

FIG. 2 is an atomic force microscope (AFM) image of the surface of a mechanically defibrated sheet, a semiconductor material in the embodiment of the present invention.

FIG. 3 is an XRD spectrum of the mechanically defibrated sheet, a semiconductor material in the embodiment of the present invention.

FIG. 4 is a complex plane impedance graph and a Nyquist diagram of the mechanically defibrated sheet, a semiconductor material in the embodiment of the present invention.

FIG. 5 is a graph showing current-voltage characteristics of the mechanically defibrated sheet, a semiconductor material in the embodiment of the present invention.

FIG. 6 is a graph showing the frequency analysis results of current when applying a high voltage, of the mechanically defibrated sheet, a semiconductor material in the embodiment of the present invention.

FIG. 7 is a graph showing resistance-voltage characteristics of the mechanically defibrated sheet, a semiconductor material in the embodiment of the present invention.

FIG. 8 is a complex plane impedance graph of a phosphorylated defibrated sheet, a semiconductor material in the embodiment of the present invention.

FIG. 9 is a graph showing current-voltage characteristics of the phosphorylated defibrated sheet, a semiconductor material in the embodiment of the present invention.

FIG. 10 is a graph showing resistance-voltage characteristics of the phosphorylated defibrated sheet, a semiconductor material in the embodiment of the present invention.

FIG. 11 is a complex plane impedance graph of a chitosan sheet, a semiconductor material in the embodiment of the present invention.

FIG. 12 is a graph showing current-voltage characteristics of the chitosan sheet, a semiconductor material in the embodiment of the present invention.

FIG. 13 is a graph showing the frequency analysis results of current in an N-type negative resistance region of the chitosan sheet, a semiconductor material in the embodiment of the present invention.

FIG. 14 are side views (a) to (c), a perspective view (d) and a side view (e) showing a method for producing a multilayer semiconductor material in the embodiment of the present invention by a MEMS method.

### DETAILED DESCRIPTION OF THE INVENTION

The embodiment of the present invention will now be described based on the drawings and Examples.

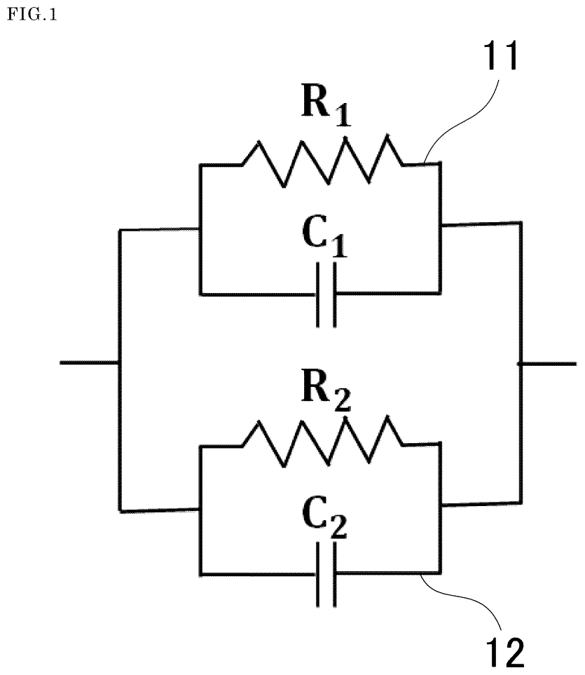

FIG. 1 to FIG. 13 show a semiconductor material in the embodiment of the present invention.

The semiconductor material in the embodiment of the present invention includes a bulk semiconductor, and has fibers containing, as a main component, a filament derived from at least any one of a wood material, a plant fiber (pulp), an animal, an alga, a microorganism and a product produced by a microorganism. As shown in the structural formula below, the fibers includes a filament in which hydroxyl groups (OH groups) and carbonyl groups (C—O groups) are bound to cellulose, a polysaccharide, represented by the molecular formula (C₆H₁₀O₅)ₙ.

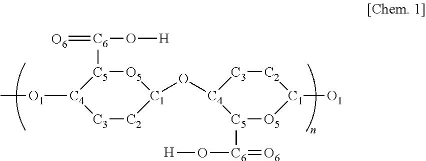

The fibers include, for example, pulp, a cellulose fiber or a cellulose nanofiber (CNF). In addition, the fibers are amorphous, but nanocrystals may exist therein. In addition, the fibers may have an atomic vacancy. The fibers are formed using a wood material or a plant fiber (pulp) as a raw material by a mechanical defibration method or a chemical defibration method such as a phosphate esterification method.

Subsequently, the action will be described.

In the semiconductor material in the embodiment of the present invention, the fibers have cellulose in which β-glucoses are polymerized, and thus the molecules are bound by hydrogen bonds to easily form a thin film sheet shape. In addition, hydroxyl groups (OH group) and carbonyl groups (C—O group) are bound to the cellulose, and thus by behavior like chained protonic solitons, an electric double layer, a base of proton transfer, can be instantly formed. A high dielectric domain structure is formed by the formed electric double layer, and also proton tunneling (solitonized proton) is formed by the quantum size effect, and therefore semiconductor characteristics can be expressed.

FIG. 1 shows an equivalent circuit of a semiconductor material in the embodiment of the present invention. As shown in FIG. 1, the semiconductor material in the embodiment of the present invention is represented by an equivalent circuit in which a first RC parallel circuit 11 and a second RC parallel circuit 12 are connected in parallel, and the second RC parallel circuit 12 has resistance R₂ with a greater resistance value than that of resistance R₁ of the first RC parallel circuit 11, and a condenser C₂ with a greater capacity than that of a condenser C₁ of the first RC parallel circuit 11. The first RC parallel circuit 11 and the second RC parallel circuit 12 indicate an electric double layer in the fibers, and therefore semiconductor characteristics can be expressed.

The semiconductor material in the embodiment of the present invention includes fibers containing, as a main component, a filament derived from at least any one of a wood material, a plant fiber (pulp), an animal, an alga, a microorganism and a product produced by a microorganism, is earth-conscious and is less harmful to living organisms.

Hereinafter, semiconductor materials in the embodiment of the present invention were produced as Examples and various measurements were carried out. It should be noted that Examples below are provided only for the illustration of the present invention and the reference of specific aspects thereof, and do not limit and restrict the scope of the invention disclosed in the present application.

### Example 1

### <Sample 1>

A semiconductor material of sample 1 in the embodiment of the present invention was produced as described below.

Kenaf stems from Bangladesh were used as a raw material, the kenaf stems were dried and stored and then soaked in 20° C. water for two weeks. After two weeks, the white bark on the surface thereof was peeled and dried. After drying it was defibrated by a high-pressure homogenizer to obtain pulped fibers (bast fibers). The sheet-shaped pulp was soaked in distilled water at a concentration of 3% for 5 hours and disintegrated by a pulper for 30 minutes. For the disintegrated slurry, 2% disintegrated pulp was crushed by a planetary ball mill using a zirconium ball at a rotation number of 100 rpm for 10 hours. After crushing, the 2% disintegrated pulp crushed slurry was dropped on the Si substrate of a spin coater and rotated at 500 rpm to produce a thin film. After this, water was vaporized and dried on a 100° C. hot plate to make a kenaf sheet.

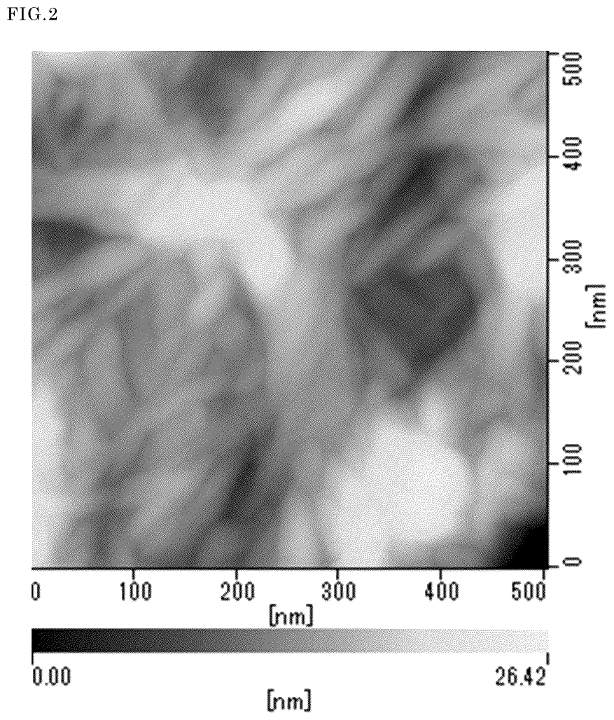

The surface of the sheet-shaped sample 1 was observed by an atomic force microscope (AFM), and the results are shown in FIG. 2. As shown in FIG. 2, it was verified that a number of long and thin substances with a width of 30 to 50 nm were distributed on the surface of the sample 1. The width of each of CNFs is 3 to 4 nm, and thus these substances are considered to be the bundles of CNFs.

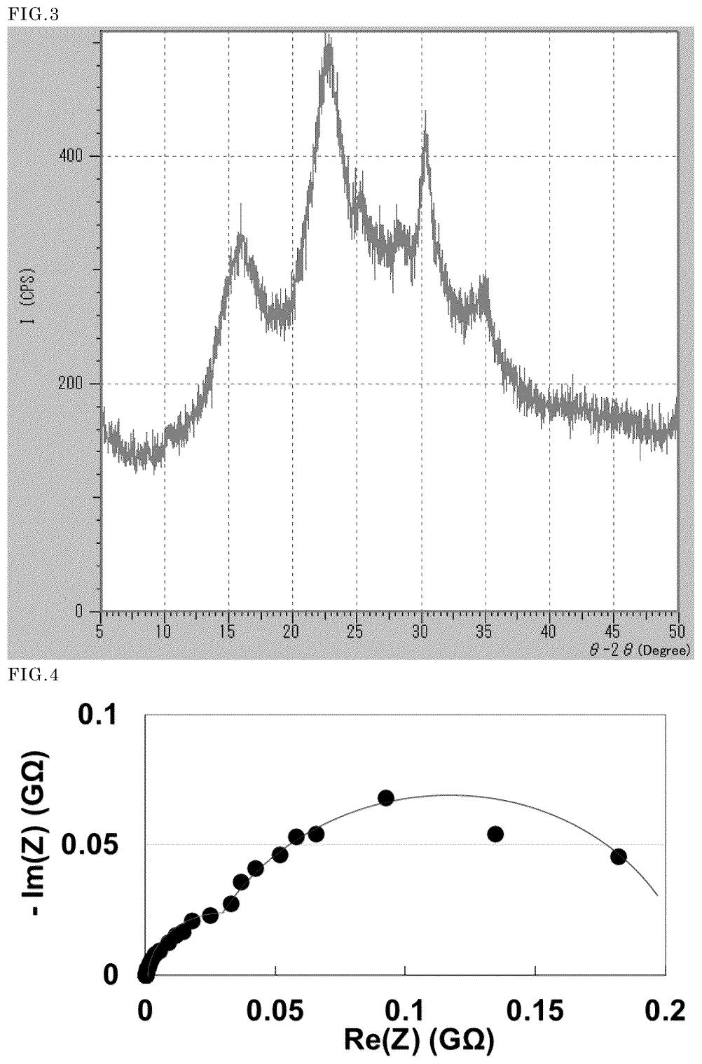

The sample 1 was analyzed by an X-ray diffraction (XRD) method. The obtained XRD spectrum is shown in FIG. 3. As shown in FIG. 3, broad peaks were recognized, and thus it was verified that the sample 1 was amorphous.

It was also verified that in the sample 1, the measured density was 1.6 g/cm³ and the specific gravity was low, 2 or less. It was also verified that the sample 1 could operate in a range of-269° C. to 200° C. up to 300 V in a furnace for low and medium temperatures. In addition, the specific surface area of the sample 1 was measured by a BET method, and the result was 800 m²/g.

A pair of metal electrodes were provided on both surfaces of the sample 1 in a thin film sheet shape so that the sample 1 was placed between the electrodes, and various measurements were carried out. First, an AC signal was applied between the electrodes by an AC impedance method, and the absolute value of impedance and the phase difference of voltage and current of the sample 1 were measured. It should be noted that both the electrodes are Al electrodes. A graph obtained by plotting the measurement results on a complex plane is shown in FIG. 4. As shown in FIG. 4, it was verified that the measurement results were plotted along a shape having two small and large aligned arcs. From the results, the sample 1 is considered to be represented by the equivalent circuit shown in FIG. 1.

Therefore, in the equivalent circuit shown in FIG. 1, the electrical resistivity of resistances R₁ and R₂ and the electrical capacity of the condensers C₁ and C₂ were changed, and the Nyquist diagram corresponding best with the measurement results shown in FIG. 4 was obtained by the least squares method and is shown with the solid line in FIG. 4. The electrical resistivity and the electrical capacity at this time were R₁=0.35 kΩm, R₂=8 kΩm, C₁=2×10⁻⁹ F and C₂=5×10⁻⁸ F.

As shown in FIG. 4, the measurement results and the Nyquist diagram almost correspond with each other, and thus it was verified that the sample 1 was equivalent to a lumped constant condenser having two macroscopic condensers (electric double layer) shown in FIG. 1, and a semiconductor having two bands, a low current low resistance band and a high current high resistance band, was formed. From the results, the sample 1 is considered to express the phenomenon of not a pn junction but bulk semiconductor.

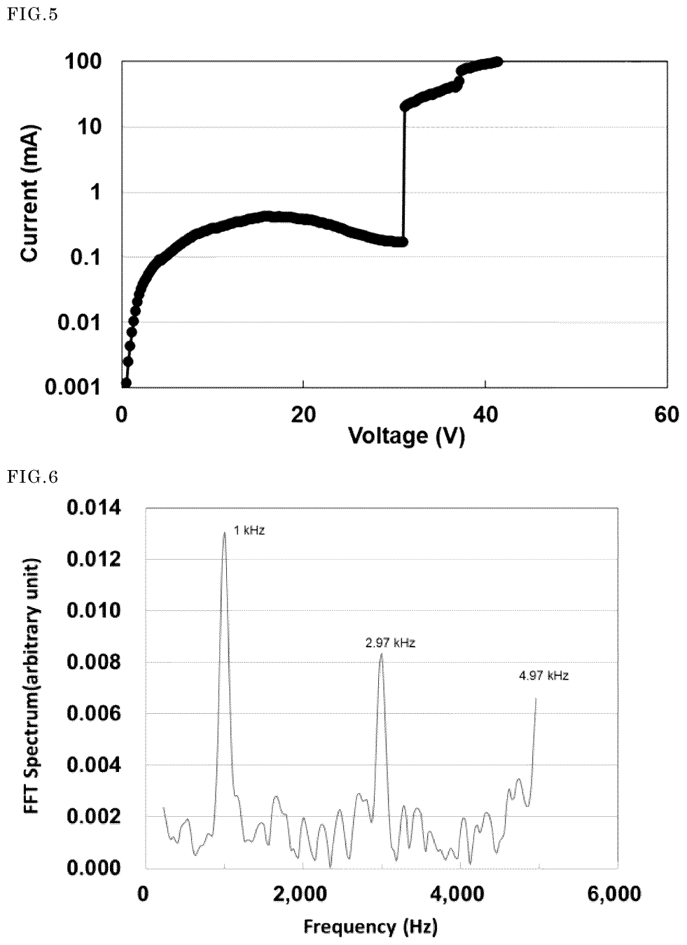

Next, a voltage was applied between the electrodes of the sample 1 to measure current-voltage characteristics at room temperature. The results are shown in FIG. 5. As shown in FIG. 5, it was verified that current was reduced between about 15 and 33 V and the sample 1 showed N-type negative resistance. From the results, it can be said that the sample 1 is a semiconductor.

In addition, a voltage was applied between the electrodes of the sample 1 to measure current flowing between the electrodes, and the frequency analysis was carried out. The results are shown in FIG. 6. As shown in FIG. 6, harmonic peaks were observed at about 1 kHz, 3 kHz and 5 kHz. From the results, the sample 1 is considered to perform DC/AC conversion. It should be noted that the results are similar to the Gunn effect, which is recognized in GaAs (gallium arsenide) semiconductors.

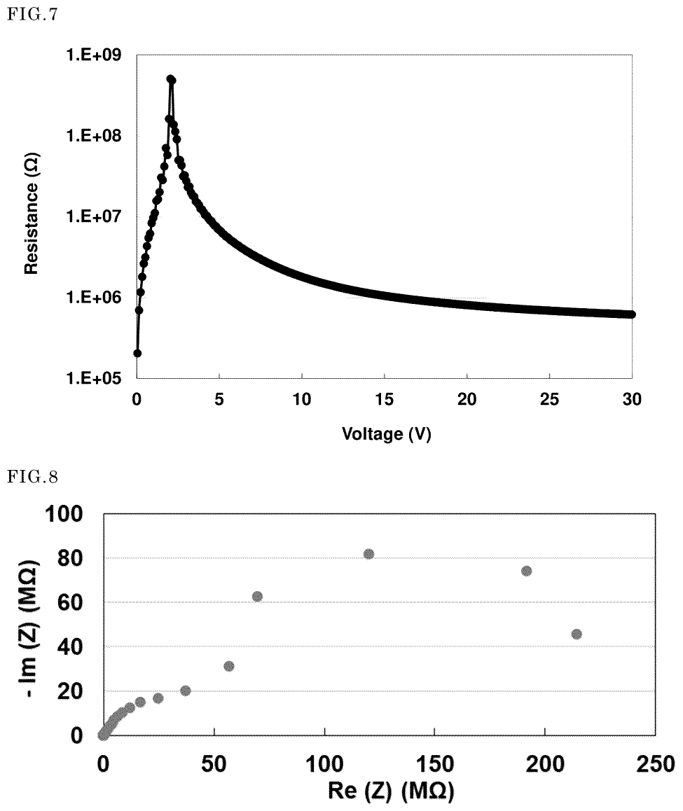

In addition, a voltage was applied between the electrodes of the sample 1 to measure resistance-voltage characteristics at room temperature. The measurement results are shown in FIG. 7. As shown in FIG. 7, it was verified that the resistance values of the sample 1 rapidly increased from 0 V to about 2 V by about 3 to 4 orders with increases in voltage, and then was reduced by about 3 orders. The results are considered to be due to a switching effect between metal and an insulator. This is considered to be not the effect of a pn junction semiconductor, but the effect of a semiconductor having two bands, a low current low resistance band and a high current high resistance band, specific to an n-type bulk semiconductor having N-type negative resistance.

### Example 2

### <Sample 2>

A semiconductor material of sample 2 in the embodiment of the present invention was produced as described below.

Bleached unbeaten kraft pulp derived from a needle-leaved tree (whiteness 85%) was used as a raw material, and 10 g of the pulp was soaked in a mixed solution of urea (12 g) and NH₄H₂PO₄ (4.5 g) added to distilled water (15 g). The soaked pulp was taken from the mixed solution and dried, and then hardened at 165° C. for 10 minutes. The hardened pulp was put in distilled water to obtain a 2% aqueous solution, and caustic soda was further added thereto to maintain pH 12 and carry out neutralization. The aqueous solution was defibrated by a high-pressure homogenizer to make a dispersed liquid of cellulose fibers with a diameter of 30 to 10 nm. The slurry distributed liquid (2% concentration) was formed into a sheet using a 50° C. heated doctor blade by a doctor blade method.

It was verified that in the sample 2, the measured density was 1.5 g/cm³ and the specific gravity was low, 2 or less. It was also verified that the sample 2 could operate in a range of −269° C. to 200° C. up to 300 V in a furnace for low and medium temperatures. In addition, the specific surface area of the sample 2 was measured by a BET method, and the result was 750 m²/g.

A pair of metal electrodes were provided on both surfaces of the sample 2 in a thin film sheet shape so that the sample 2 was placed between the electrodes, and various measurements were carried out. First, an AC signal was applied between the electrodes by the AC impedance method, and the absolute value of impedance and the phase difference of voltage and current of the sample 2 were measured. It should be noted that one electrode is an Al electrode and another electrode is a Cu electrode. A graph obtained by plotting the measurement results on a complex plane is shown in FIG. 8. As shown in FIG. 8, it was verified that the measurement results were plotted along a shape having two small and large aligned arcs. From the results, the sample 2 is considered to be represented by the equivalent circuit shown in FIG. 1.

Therefore, in the equivalent circuit shown in FIG. 1, the electrical resistivity of resistances R₁ and R₂ and the electrical capacity of the condensers C₁ and C₂ were changed, and the Nyquist diagram corresponding best with the measurement results shown in FIG. 8 was obtained by the least squares method. The electrical resistivity and electrical capacity at this time were R₁=1.4 kΩm, R₂=5.7 km, C₁=1.4×10⁻⁶ F and C₂=2.4×10⁻⁵ F.

The measurement results and the Nyquist diagram almost correspond with each other, and thus it was verified that the sample 2 was equivalent to a lumped constant condenser having two macroscopic condensers (electric double layer) shown in FIG. 1, and a semiconductor having two bands, a low current low resistance band and a high current high resistance band, was formed. From the results, the sample 1 is considered to express the phenomenon of not a pn junction but bulk semiconductor.

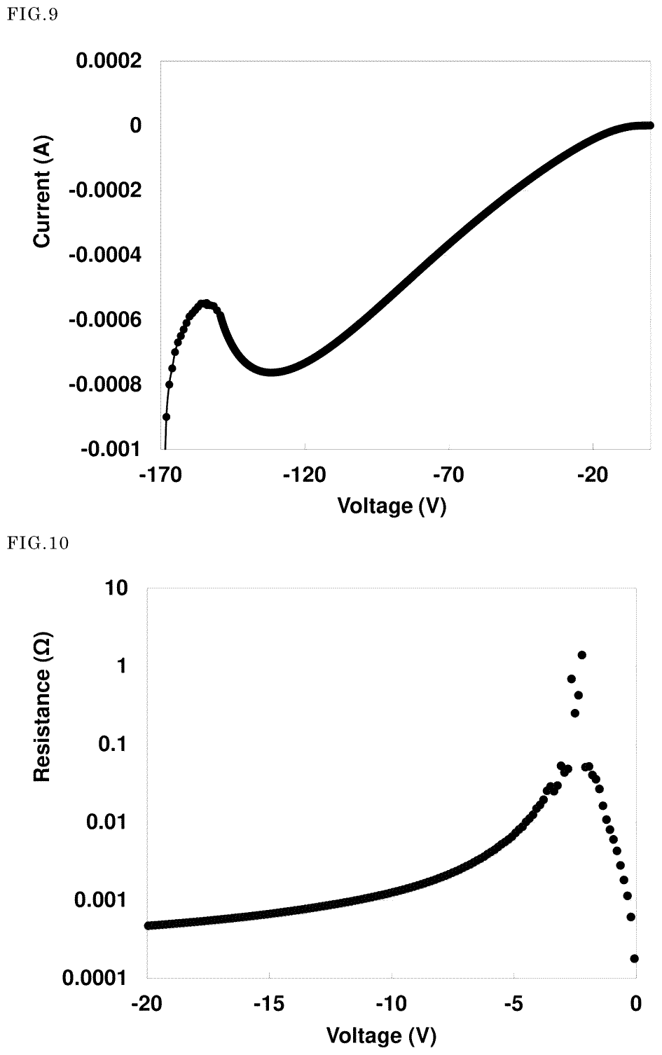

Next, a voltage was applied between the electrodes of the sample 2 to measure current-voltage characteristics at room temperature. The results are shown in FIG. 9. As shown in FIG. 9, it was verified that current was reduced between about −150 and −125 V and the sample 2 showed N-type negative resistance. From the results, it can be said that the sample 2 is a semiconductor.

In addition, a voltage was applied between the electrodes of the sample 2 to measure resistance-voltage characteristics at room temperature. The measurement results are shown in FIG. 10. As shown in FIG. 10, it was verified that the resistance values of the sample 2 rapidly increased from 0 V to about −2.5 V by about 3 to 4 orders with decreases in voltage, and then was reduced by about 3 orders. The results are considered to be due to a switching effect between metal and an insulator. This is considered to be not the effect of a pn junction semiconductor, but the effect of a semiconductor having two bands, a low current low resistance band and a high current high resistance band, specific to an n-type bulk semiconductor having N-type negative resistance.

### Example 3

### <Sample 3>

A semiconductor material of sample 3 in the embodiment of the present invention was produced as described below.

Chitin isolated from red snow crab shells was used as a raw material, 10 g of the chitin was put in a 48% sodium hydroxide solution, the obtained mixture was boiled at 120° C. for 30 minutes and then separated by filtration, and sodium hydroxide was completely removed by washing with water. The slurry separated by filtration was crushed by a planetary ball mill using a zirconium ball at a rotation number of 200 rpm for 20 hours. The obtained 3% crushed slurry was dropped on the Si substrate of a spin coater, and rotated at 800 rpm to make a thin film. After this, water was vaporized and dried on a 100° C. hot plate to produce a chitosan sheet.

It was verified that in the sample 3, the measured density was 2.1 g/cm³ and the specific gravity was relatively low. It was also verified that the sample 3 could operate in a range of −50° C. to 200° C. up to 300 V in a furnace for low and medium temperatures.

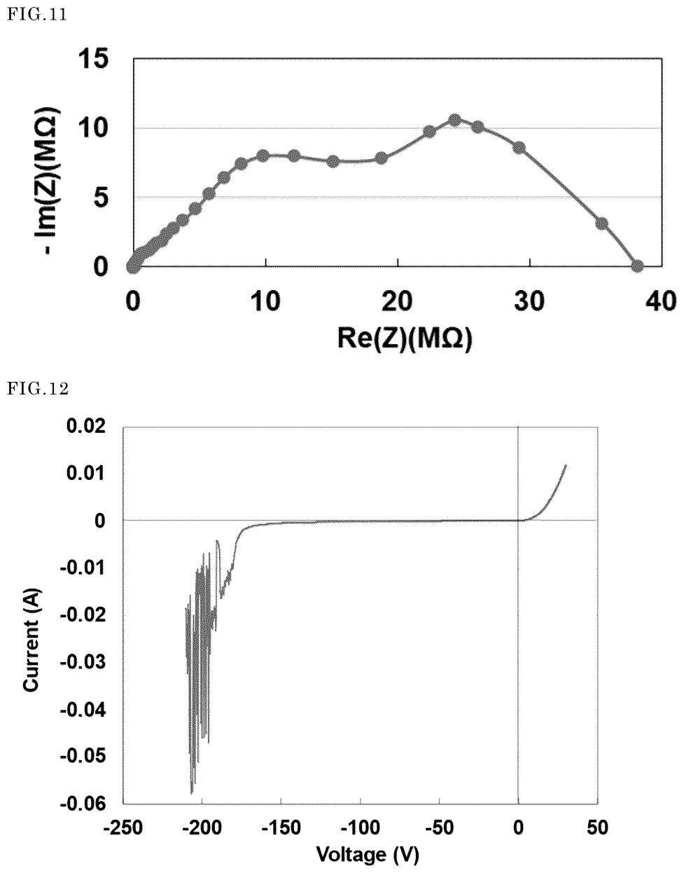

A pair of metal electrodes were provided on both surfaces of the sample 3 in a thin film sheet shape so that the sample 3 was placed between the electrodes, and various measurements were carried out. First, an AC signal was applied between the electrodes by the AC impedance method, and the absolute value of impedance and the phase difference of voltage and current of the sample 3 were measured. It should be noted that one electrode is an Al electrode and another electrode is a Cu electrode. A graph obtained by plotting the measurement results on a complex plane is shown in FIG. 11. As shown in FIG. 11, it was verified that the measurement results were plotted along a shape having roughly two small and large semicircles. From the results, the sample 3 is considered to be represented by the equivalent circuit shown in FIG. 1.

Therefore, in the equivalent circuit shown in FIG. 1, the electrical resistivity of resistances R₁ and R₂ and the electrical capacity of the condensers C₁ and C₂ were changed, and the Nyquist diagram corresponding best with the measurement results shown in FIG. 11 was obtained by the least squares method. The electrical resistivity and electrical capacity at this time were R₁=R₂=3.8 kΩm, C₁=3.3×10⁻⁷ F and C₂=9.3×10⁻⁷ F.

The measurement results and the Nyquist diagram almost correspond with each other, and thus it was verified that the sample 3 was equivalent to a lumped constant condenser having two macroscopic condensers (electric double layer) shown in FIG. 1, and a semiconductor having two bands, a low current low resistance band and a high current high resistance band, was formed. From the results, the sample 3 is considered to express the phenomenon of not a pn junction but bulk semiconductor.

Next, a voltage was applied between the electrodes of the sample 3 to measure current-voltage characteristics at room temperature. In the measurement, a voltage was applied while scanning at a rate of 1.24V/s from about −210 V toward about +30 V. The results are shown in FIG. 12. As shown in FIG. 12, it was verified that the current value vibrated between about −210 V and about −170 V and the sample 3 showed N-type negative resistance. It was also verified that current was zero between −170 V and 0 V because of entering into a resistance region of 100 kΩ; however, current dramatically flowed when entering into a positive voltage region beyond 0 V, and a rectification effect was shown.

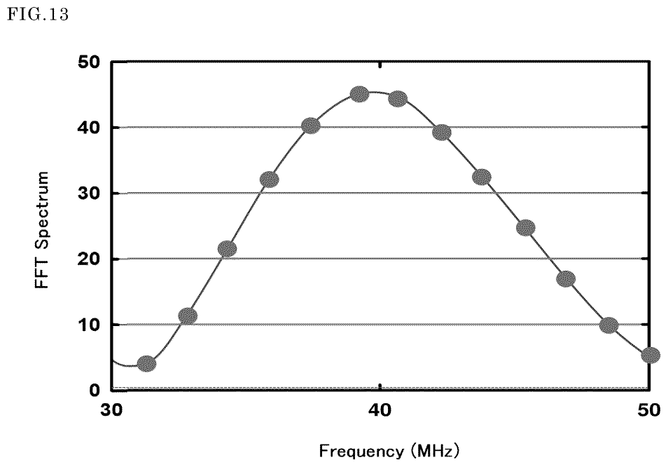

The frequency analysis of the current vibration in the N-type negative resistance region between about −210 V and about −170 V was then carried out by an oscilloscope. The results are shown in FIG. 13. As shown in FIG. 13, the peak was verified at a site where the mean frequency is about 40 MHz. From the results, the sample 3 is considered to perform DC/AC conversion.

The defibration treatment, fiber state (classification of crystal and formless (amorphous)), density, electrical resistivity and electrical capacity of the sample 1 to sample 3 are summarized and shown in Table 1.

TABLE 1

| | | Defibration | | | Electrical | |
|---|---|---|---|---|---|---|
| | | treatment | | Density | resistivity | Electrical |
| Sample | Type of Sheet | method | Fiber state | (g/cm³) | (kΩm) | capacity (F) |
| 1 | Mechanically | Mechanical | Formless | 1.6 | R₁ = 0.35 | C₁ = 2 × 10⁻⁹ |
| | defibrated sheet | ball mill | | | R₂ = 1.8 | C₂ = 5 × 10⁻⁸ |
| 2 | Phosphorylated | Chemical | Formless | 1.5 | R₁ = 1.4 | C₁ = 1.4 × 10⁻⁶ |
| | defibrated sheet | phosphate | (including 5% | | R₂ = 5.7 | C₂ = 2.4 × 10⁻⁵ |
| | | esterification | nanocrystals) | | | |
| 3 | Chitosan sheet | Mechanical | Formless | 2.1 | R₁ = R₂ = | C₁ = 3.3 × 10⁻⁷ |
| | | ball mill | | | 3.8 | C₂ = 9.3 × 10⁻⁷ |

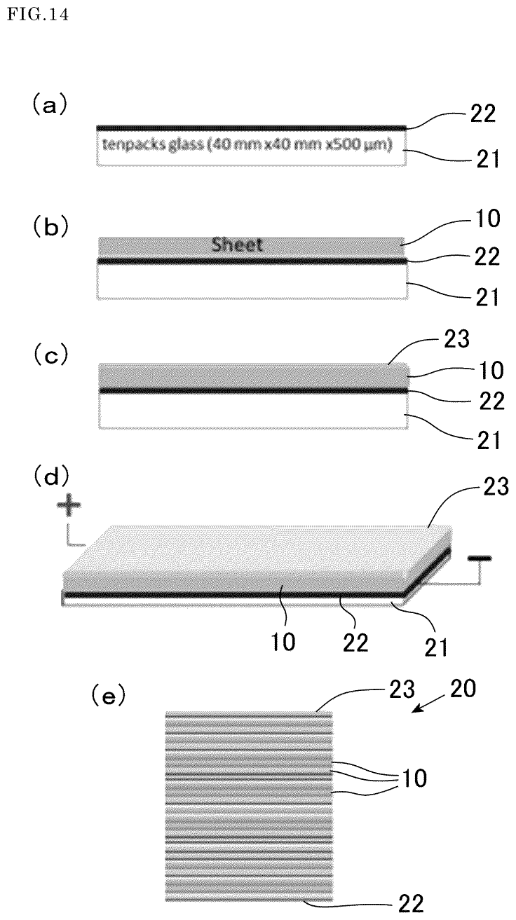

FIG. 14 shows a multilayer semiconductor material in the embodiment of the present invention.

As shown in FIG. 14, the multilayer semiconductor material in the embodiment of the present invention is produced using the sheet-shaped semiconductor material in the embodiment of the present invention by the MEMS method as described below. As shown in FIG. 14 (a), first, a Cu layer (thickness 500 nm) 22 is formed on the surface of a glass substrate (40×40×0.5 mm) 21 by sputtering. Subsequently, a sheet-shaped semiconductor material 10 is put on the Cu layer 22 as shown in FIG. 14 (b), and an Al layer (thickness 500 nm) 23 is further formed thereon by sputtering as shown in FIG. 14 (c). Thereby, a material shown in FIG. 14 (d) having the Cu layer 22 and the Al layer 23 as metal electrodes on both surfaces of the sheet-shaped semiconductor material 10 can be produced. It should be noted that this structure corresponds to those of the materials having metal electrodes on both surfaces of the sample 1 to sample 3 used in various measurements in Examples 1 to 3.

Subsequently, the glass substrate 21 was removed, and the remaining material was used as a base body. By laminating a plurality of the base bodies, a multilayer semiconductor material 20 in the embodiment of the present invention shown in FIG. 14 (e) can be produced. In the produced multilayer semiconductor material 20, the Al layer 23 on the top of the base bodies and the Cu layer 22 on the bottom of the base bodies are terminals, and a plurality of the semiconductor materials 10 are joined in series.

As described above, the multilayer semiconductor material 20 in the embodiment of the present invention includes a laminated body in which a plurality of the semiconductor materials 10 in the embodiment of the present invention are laminated, and can be a solid quantum semiconductor in which parallel equivalent circuits are bonded in an electric lumped constant manner.

### INDUSTRIAL APPLICABILITY

The semiconductor material and multilayer semiconductor material according to the present invention can be widely used from the weak electric field of e.g. mobile phones, drones, and wall-mounted televisions, to the strong electric field of e.g. not only motor vehicles but also ships and airplanes. More specifically, they can be utilized for e.g. an AC transmitter, control equipment and an overcurrent prevention switch for microelectronic circuits. They can be also utilized for e.g. electronic and electric infrastructure such as power source modules for e.g. lighting arresters, welding and overdischarging prevention, various amplifiers, microwave oscillators, pump sources of parametric amplifiers, sensors for e.g. police radars, door opening/closing systems, trespass sensing systems, noise filters, pedestrian safe systems, control equipment for microelectronics, remote vibration detectors, shunt regulators, protection circuits and transmitters.

### REFERENCE SIGNS LIST

10: Semiconductor material
11: First RC parallel circuit
12: Second RC parallel circuit
20: Multilayer semiconductor material
21: Glass substrate
22: Cu layer
23: Al layer

1. A semiconductor material, having fibers containing, as a main component, a filament derived from at least any one of a wood material, a plant fiber (pulp), an animal, an alga, a microorganism and a product produced by a microorganism, and having N-type negative resistance.

2. The semiconductor material according to claim 1, which is an n-type semiconductor.

3. The semiconductor material according to claim 1, wherein the fibers comprise bundles of cellulose nanofibers (CNFs) and a width of the bundles is 30 to 50 nm.

4. The semiconductor material according to claim 1, wherein the fibers comprise bundles of cellulose nanofibers (CNFs) and an aspect ratio of the bundles is 1 to 200.

5. The semiconductor material according to claim 1, wherein the fibers are fibers in which a plurality of hydroxy groups and a plurality of carbonyl groups are bound to cellulose.

6. The semiconductor material according to claim 1, comprising a bulk semiconductor represented by an equivalent circuit in which a first RC parallel circuit and a second RC parallel circuit are connected in parallel,
wherein the second RC parallel circuit has resistance with a greater resistance value than that of resistance of the first RC parallel circuit and a condenser with a greater capacity than that of a condenser of the first RC parallel circuit.

7. The semiconductor material according to claim 1, wherein the fibers are amorphous.

8. A multilayer semiconductor material, comprising a laminated body in which a plurality of the semiconductor materials according to claim 1 are laminated.

9. The semiconductor material according to claim 2, wherein the fibers comprise bundles of cellulose nanofibers (CNFs) and a width of the bundles is 30 to 50 nm.

10. The semiconductor material according to claim 2, wherein the fibers comprise bundles of cellulose nanofibers (CNFs) and an aspect ratio of the bundles is 1 to 200.

11. The semiconductor material according to claim 2, wherein the fibers are fibers in which a plurality of hydroxy groups and a plurality of carbonyl groups are bound to cellulose.

12. The semiconductor material according to claim 2, comprising a bulk semiconductor represented by an equivalent circuit in which a first RC parallel circuit and a second RC parallel circuit are connected in parallel,
wherein the second RC parallel circuit has resistance with a greater resistance value than that of resistance of the first RC parallel circuit and a condenser with a greater capacity than that of a condenser of the first RC parallel circuit.

13. The semiconductor material according to claim 2, wherein the fibers are amorphous.

14. A multilayer semiconductor material, comprising a laminated body in which a plurality of the semiconductor materials according to claim 2 are laminated.
